(19) United States
(12) Patent Application Publication
(10) Pub. No.: US 2023/0311236 A1
(43) Pub. Date: Oct. 5, 2023

(54) SPATTER DETECTION METHOD

(71) Applicant: HONDA MOTOR CO., LTD., Tokyo (JP)

(72) Inventors: Xihao TAN, Tokyo (JP); Hitoshi SAITO, Tokyo (JP); Shinya WATANABE, Tokyo (JP)

(21) Appl. No.: 18/180,873

(22) Filed: Mar. 9, 2023

(30) Foreign Application Priority Data
Mar. 31, 2022 (CN) 202210346310.3

(51) Int. Cl. B23K 11/25; B23K 11/11

(52) U.S. Cl. CPC B23K 11/258; B23K 11/115; B23K 2101/18

(57) ABSTRACT

A spot welding method using a welding apparatus includes supplying a pulse-shaped welding current to a workpiece, the pulse-shaped welding current being generated when a welding power circuit alternately repeats power distribution control and a power distribution pause over a plurality of cycles, and maintaining, under the power distribution control, the welding current within a set peak current range in a peak holding section. A spatter detection method includes: a step of acquiring an average value of voltage detection values Vpv detected by a voltage sensor in the peak holding section for each of the cycles; and a step of determining whether or not the spatter occurs, based on a difference value between an average value of the voltage detection values Vpv in the peak holding section for an N-th cycle and an average value of the voltage detection values Vpv in the peak holding section for an (N−1)-th cycle.

This application is based on and claims the benefit of priority from Chinese Patent Application No. 202210346310.3, filed on 31 Mar. 2022, the content of which is incorporated herein by reference.

### BACKGROUND OF THE INVENTION

### Field of the Invention

The present invention relates to a spatter detection method. More specifically, the present invention relates to a spatter detection method for detecting an occurrence of spatter in spot welding for joining a workpiece by supplying a pulse-shaped welding current.

### Related Art

In the case of welding a plurality of metal plates to each other, spot welding using a spot welding apparatus is performed. In spot welding, power is distributed between a pair of electrode chips in a state in which the plurality of metal plates as workpieces are sandwiched between the pair of electrode chips, and in this manner, a nugget is generated between the plurality of metal plates to weld the plurality of metal plates.

In a spot welding method proposed by the applicant disclosed in PCT International Publication No. WO2020/050011, a welding current having a pulse-shaped waveform is supplied to a plurality of metal plates over a plurality of cycles in a state in which the plurality of metal plates is sandwiched by a pair of electrodes, and in this manner, the plurality of metal plates is welded to each other.
Patent Document 1: PCT International Publication No. WO2020/050011
Patent Document 2: Japanese Unexamined Patent Application, Publication No. 2010-149144

### SUMMARY OF THE INVENTION

In spot welding, while a welding current is supplied to a metal plate, a phenomenon called “spatter” occurs in which part of the metal plate is molten and scattered. When the spatter occurs, welding strength may decrease, and thus it is preferable to detect the spatter immediately when the spatter occurs.

Japanese Unexamined Patent Application, Publication No. 2010-149144 discloses a technique for detecting an occurrence of spatter based on a change in a resistance value during welding, using the fact that the resistance value of a workpiece decreases when spatter occurs. However, it is necessary to detect a voltage between a pair of electrode chips in order to monitor the resistance value of the workpiece. Therefore, in the technique disclosed in Japanese Unexamined Patent Application, Publication No. 2010-149144, it is necessary to provide a voltage detection line for detecting a voltage in the vicinity of the electrode chips. However, since the vicinity of the electrode chips is exposed to a high temperature during welding, the voltage detection line needs to be replaced periodically, which may increase costs and cycle time.

An object of the present invention is to provide a spatter detection method capable of detecting an occurrence of spatter using an existing sensor without newly providing a voltage detection line in the vicinity of electrode chips.

(1) A spatter detection method according to the present invention is a method for detecting an occurrence of spatter at the time of joining a workpiece, which is a multilayer body of a plurality of plates, using a welding apparatus including a pair of electrodes, a welding power circuit connected to the pair of electrodes, and a voltage sensor configured to detect a voltage in the welding power circuit. A spot welding method using the welding apparatus includes supplying a pulse-shaped welding current to the workpiece, the pulse-shaped welding current being generated when the welding power circuit alternately repeats power distribution control and a power distribution pause over a plurality of cycles while the workpiece is sandwiched and pressurized by the pair of electrodes, and maintaining, under the power distribution control, the welding current within a set peak current range in a peak holding section. The spatter detection method includes: a step of acquiring voltage detection values detected by the voltage sensor in the peak holding section for each of the cycles; and a step of determining whether or not the spatter occurs, based on a difference value between the voltage detection values in the peak holding section for an N-th cycle (N being an integer equal to or greater than 2) and the voltage detection values in the peak holding section for an M-th cycle (M being an integer smaller than N).

(2) In this case, preferably, the M-th cycle is a cycle immediately before the N-th cycle.

(3) In this case, preferably, the spatter detection method further includes a step of calculating an average value of the voltage detection values in the peak holding section for each of the cycles, and it is determined that the spatter occurs when an average difference value is larger than a predetermined first threshold value, the average difference value being obtained by subtracting the average value for the N-th cycle from the average value for the M-th cycle.

(4) A spatter detection method according to the present invention is a method for detecting an occurrence of spatter at the time of joining a workpiece, which is a multilayer body of a plurality of plates, using a welding apparatus including a pair of electrodes, a welding power circuit connected to the pair of electrodes, and a voltage sensor configured to detect a voltage in the welding power circuit. A spot welding method using the welding apparatus includes supplying a pulse-shaped welding current to the workpiece, the pulse-shaped welding current being generated when the welding power circuit alternately repeats power distribution control and a power distribution pause over a plurality of cycles while the workpiece is sandwiched and pressurized by the pair of electrodes, and maintaining, under the power distribution control, the welding current within a set peak current range in a peak holding section. The spatter detection method includes: a step of acquiring voltage detection values detected by the voltage sensor in the peak holding section for each of the cycles; and a step of determining whether or not the spatter occurs, based on a reduced velocity with respect to a change in a number of cycles of the voltage detection values.

(5) In this case, preferably, the spatter detection method further includes a step of calculating an average value of the voltage detection values in the peak holding section for each of the cycles, and it is determined that the spatter occurs when a reduced velocity with respect to a change in the number of cycles of the average value is larger than a predetermined second threshold value.

(1) The circuit formed by a combination of the workpiece, the pair of electrodes that sandwich the workpiece, and the welding power circuit connected to the pair of electrodes can be regarded as an RL series circuit in which the resistance element corresponding to the workpiece and the inductance element corresponding to the welding power circuit are connected in series. For this reason, when the welding current, which changes with time in a pulse shape, is supplied to the workpiece by alternately repeating the power distribution control and the power distribution pause by the welding power circuit over a plurality of cycles, the voltage sensor provided in the welding power circuit is affected by the inductance element, and thus cannot detect the voltage between the pair of electrodes, that is, the voltage of the workpiece. Therefore, in the present invention, the voltage detection value detected by the voltage sensor in the peak holding section in which the welding current is maintained within the set peak current range is acquired for each cycle, and the presence or absence of the occurrence of spatter is determined, based on the difference value between the voltage detection values in the peak holding section for the N-th cycle and the voltage detection values in the peak holding section for the M-th cycle before the N-th cycle. In such a peak holding section, since the welding current changes little over time, the voltage sensor provided in the welding power circuit can detect the voltage of the workpiece while ignoring the influence of the inductance element. Therefore, according to the present invention, the voltage sensor provided in the welding power circuit can detect the voltage drop in the workpiece due to the occurrence of spatter while the welding current is being supplied, and can detect the occurrence of spatter as a result.

(2) When the pulse-shaped welding current as described above continues to be supplied over a plurality of cycles, the voltage of the workpiece will gradually change even when the spatter does not occur. Therefore, in the present invention, the voltage detection value in the peak holding section for the M-th cycle (i.e., M=N−1) immediately before the N-th cycle is used as a comparison target for the voltage detection value in the peak holding section for the N-th cycle, whereby it is possible to determine the presence or absence of the occurrence of spatter and the cycle of the occurrence of spatter with high accuracy.

(3) In the peak holding section, the welding current is maintained within the peak current range, but fluctuates slightly. Therefore, in the present invention, the average value of the voltage detection values in the peak holding section is calculated for each cycle, and it is determined that the spatter occurs when the difference value obtained by subtracting the average value for the N-th cycle from the average value for the M-th cycle is larger than the predetermined first threshold value. By using the average value of the voltage detection values in the peak holding section in this manner, the voltage of the workpiece can be detected while ignoring the influence caused by the slight change in the current as described above, whereby it is possible to determine the presence or absence of the occurrence of spatter and the cycle of the occurrence of spatter with high accuracy.

(4) In the present invention, the voltage detection value detected by the voltage sensor in the peak holding section in which the welding current is maintained within the set peak current range is acquired for each cycle, and the presence or absence of the occurrence of spatter is determined, based on the reduced velocity with respect to the change in the number of cycles of the voltage detection value. In such a peak holding section, since the welding current changes little over time, the voltage sensor provided in the welding power circuit can detect the voltage of the workpiece while ignoring the influence of the inductance element. Therefore, according to the present invention, the voltage sensor provided in the welding power circuit can detect the voltage drop in the workpiece due to the occurrence of spatter while the welding current is being supplied, and can detect the occurrence of spatter as a result.

(5) In the present invention, the average value of the voltage detection values in the peak holding section is calculated for each cycle, and it is determined that the spatter occurs when the reduced velocity with respect to the change in the number of cycles of the average value is larger the predetermined second threshold value. By using the average value of the voltage detection values in the peak holding section in this manner, the voltage of the workpiece can be detected while ignoring the influence caused by the slight change in the current in the peak holding section, whereby it is possible to determine the presence or absence of the occurrence of spatter and the cycle of the occurrence of spatter with high accuracy.

### BRIEF DESCRIPTION OF THE DRAWINGS

FIG. 1 is a view showing a configuration of a welding system to which a spot welding method and a spatter detection method according to one embodiment of the present invention is applied;

FIG. 2 is a diagram showing a circuit configuration of a welding power circuit;

FIG. 3 is a graph showing a relationship between an AC voltage input from an inverter circuit to a transformer and a welding current applied to a pair of electrode chips in the welding power circuit;

FIG. 4 is a view schematically showing the section of a workpiece during welding;

FIG. 5 is a flowchart showing the specific steps of welding current control in a control apparatus;

FIG. 6 is a graph showing the waveform of the welding current achieved by the welding current control of FIG. 5;

FIG. 7 is a flowchart showing the specific steps of power distribution control processing;

FIG. 8 is a graph showing waveforms of a current detection value and a voltage detection value for two cycles before and after an occurrence of spatter;

FIG. 9 is a graph obtained by plotting average values of voltage detection values for each cycle in a peak holding section;

FIG. 10 is a flowchart showing the specific steps of spatter detection processing of a first example;

FIG. 11 is a graph showing a correlation between a welding diameter formed when the welding current is continuously supplied over a prescribed cycle and a timing of the occurrence of spatter; and

FIG. 12 is a flowchart showing the specific steps of the spatter detection processing of a second example.

### DETAILED DESCRIPTION OF THE INVENTION

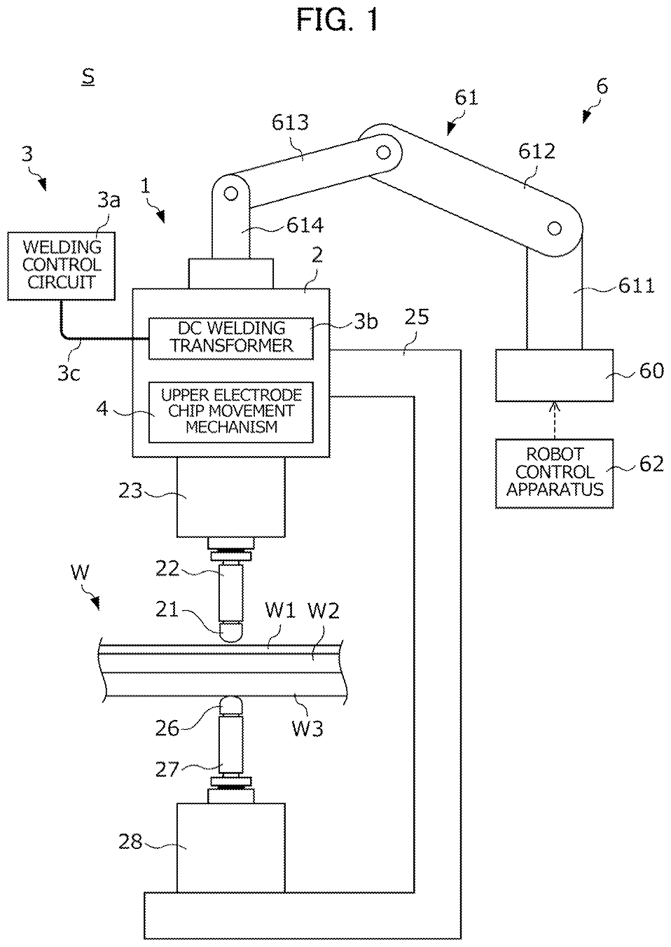

Hereinafter, one embodiment of the present invention will be described with reference to the drawings. FIG. 1 is a view showing a configuration of a welding system S to which a spot welding method and a spatter detection method according to the present embodiment is applied.

The welding system S includes a spot welding apparatus 1 as a welding gun, a workpiece W as a multilayer body of metal plates joined to each other by the spot welding apparatus 1, and a robot 6 supporting the spot welding apparatus 1.

The workpiece W is a multilayer body configured such that a plurality of metal plates is stacked on each other. In the present embodiment, a case where a first metal plate W1, a second metal plate W2, and a third metal plate W3 as three metal plates are stacked on each other in this order from the top to the bottom to form a multilayer body as the workpiece W will be described, but the present invention is not limited to such a case. The number of metal plates forming the workpiece W may be two or four or more. A case will be described below in which a thickness of the first metal plate W1 is thinner than a thickness of each of the second metal plate W2 and the third metal plate W3 and the first metal plate W1, the second metal plate W2, and the third metal plate W3 are made of the same metal, but the present invention is not limited thereto. At least one metal plate of these metal plates W1 to W3 may have a rigidity different from those of the other metal plates.

The robot 6 includes a robot body 60 attached to a floor surface, an articulated arm 61 pivotally supported on the robot body 60, and a robot control apparatus 62 that controls the robot 6. The articulated arm 61 includes a first arm portion 611 pivotally supported on a base end side by the robot body 60, a second arm portion 612 pivotally supported on a base end side by the first arm portion 611, a third arm portion 613 pivotally supported on a base end side by the second arm portion 612, and a fourth arm portion 614 pivotally supported on a base end side by the third arm portion 613 and attached to the spot welding apparatus 1 on a tip end side.

The robot control apparatus 62 drives a plurality of motors provided at the robot body 60 and the articulated arm 61 to drive each of the arm portions 611 to 614, thereby controlling the position and orientation of the spot welding apparatus 1 attached to the fourth arm portion 614 and moving later-described electrode chips 21, 26 provided at the spot welding apparatus 1 to a joint portion of the workpiece W.

The spot welding apparatus 1 includes a welding power circuit 3 as a welding current supply source, a gun body 2 on which a later-described upper electrode chip movement mechanism 4 and part of the welding power circuit 3 are mounted, the upper electrode chip 21 and the lower electrode chip 26 as a pair of electrodes, an upper electrode chip support portion 22, an upper adaptor body 23, a gun arm 25, a lower electrode chip support portion 27, and a lower adaptor body 28.

The upper electrode chip support portion 22 is in the shape of a rod extending along the vertical direction, and the upper electrode chip 21 is attached to a tip end portion of the upper electrode chip support portion 22. The upper adaptor body 23 is in a columnar shape, and connects the gun body 2 and the upper electrode chip support portion 22 to each other. The upper adaptor body 23 is, relative to the gun body 2, provided slidably along a sliding direction parallel with the axis of the upper electrode chip support portion 22.

The gun arm 25 extends to curve from the gun body 2 to below the upper electrode chip 21 in the vertical direction. The lower electrode chip support portion 27 is in the shape of a rod coaxial with the upper electrode chip support portion 22, and the lower electrode chip 26 is attached to a tip end portion of the lower electrode chip support portion 27. The lower adaptor body 28 is in a columnar shape, and connects a tip end portion of the gun arm 25 and the lower electrode chip support portion 27 to each other. As shown in FIG. 1, the lower electrode chip 26 is supported by the lower electrode chip support portion 27 to face the upper electrode chip 21 with a predetermined clearance along the axes of the chip support portions 22, 27.

The upper electrode chip movement mechanism 4 includes a cylinder, a control apparatus therefor, etc., and together with the upper electrode chip support portion 22 and the upper electrode chip 21, moves the upper adaptor body 23 back and forth along the sliding direction. With this configuration, the upper electrode chip 21 can contact an upper surface of the workpiece W with the lower electrode chip 26 contacting a lower surface of the workpiece W, and the workpiece W can be further sandwiched and pressurized by these electrode chips 21, 26.

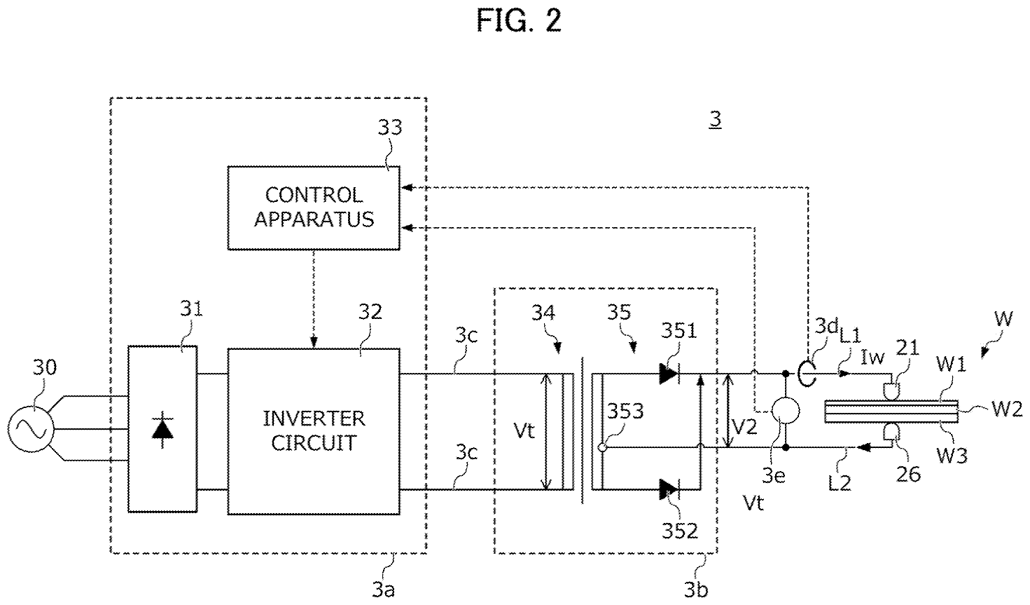

FIG. 2 is a diagram showing a circuit configuration of the welding power circuit 3. The welding power circuit 3 includes a welding control circuit 3a, a DC welding transformer 3b, power cables 3c, a current sensor 3d, and a voltage sensor 3e. The welding power circuit 3 is connected to the upper electrode chip 21 and the lower electrode chip 26 through power lines L1, L2. As shown in FIG. 1, the DC welding transformer 3b and the current sensor 3d of the welding power circuit 3 configured as described above are mounted on the gun body 2. Moreover, the welding control circuit 3a of the welding power circuit 3 is mounted on a base separated from the gun body 2, and is connected to the DC welding transformer 3b through the power cables 3c. With this configuration, the weight of the gun body 2 can be reduced.

The welding control circuit 3a includes a converter circuit 31, an inverter circuit 32, and a control apparatus 33. The DC welding transformer 3b includes a transformer 34 and a rectification circuit 35.

The converter circuit 31 performs full-wave rectification for a three-phase power input from a three-phase power source 30, thereby converting the three-phase power into a DC power and supplying the DC power to the inverter circuit 32.

The inverter circuit 32 converts the DC power input from the converter circuit 31 into a single-phase AC power, thereby outputting the single-phase AC power to the transformer 34 through the power cables 3c. More specifically, the inverter circuit 32 includes four bridge-connected switching elements. The inverter circuit 32 turns on or off these switching elements according to a gate drive signal transmitted from a gate drive circuit mounted on the control apparatus 33, thereby converting the DC power into the single-phase AC power.

The transformer 34 transforms the AC power input from the inverter circuit 32, thereby outputting the transformed AC power to the rectification circuit 35. The rectification circuit 35 rectifies the AC power input from the transformer 34, thereby outputting a DC power to between the electrode chips 21, 26 each connected to the power lines L1, L2. For example, a known full-wave rectification circuit including a combination of two rectification diodes 351, 352 and a center tap 353 is used as the rectification circuit 35.

The current sensor 3d detects a welding current supplied from the welding power circuit 3 to the chips 21, 26. The current sensor 3d is, for example, provided on the power line L1 connecting the rectification circuit 35 and the upper electrode chip 21 to each other, and to the control apparatus 33, transmits a current detection signal according to the level of the welding current flowing in the power line L1.

The voltage sensor 3e detects voltages on secondary sides (i.e., on sides of the chips 21 and 26) of the DC welding transformer 3b. The voltage sensor 3e is connected to the power lines L1 and L2 connecting the DC welding transformer 3b and the chips 21 and 26, and transmits, to the control apparatus 33, a voltage detection signal according to the level of the secondary side-voltage V2 between these power lines L1 and L2.

The control apparatus 33 includes, for example, a microcomputer that executes later-described welding current control and spatter detection processing by means of the current detection signal transmitted from the current sensor 3d and the voltage detection signal transmitted from the voltage sensor 3e and the gate drive circuit that generates the gate drive signal according to an arithmetic processing result of the microcomputer to transmit the gate drive signal to the inverter circuit 32.

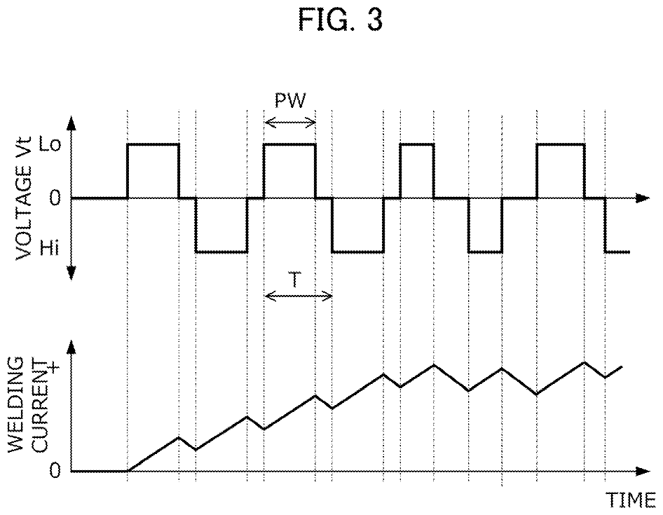

FIG. 3 is a graph showing a relationship between an AC voltage Vt input from the inverter circuit 32 to the transformer 34 and the welding current Iw applied to the electrode chips 21, 26 in the welding power circuit 3 as described above.

When the inverter circuit 32 is driven, the AC voltage Vt in the shape of a square wave as shown in FIG. 3 is outputted from the inverter circuit 32. The AC voltage output from the inverter circuit 32 is transformed in the transformer 34, and is further rectified in the rectification circuit 35. Then, the DC welding current Iw is applied to the workpiece W through the electrode chips 21, 26.

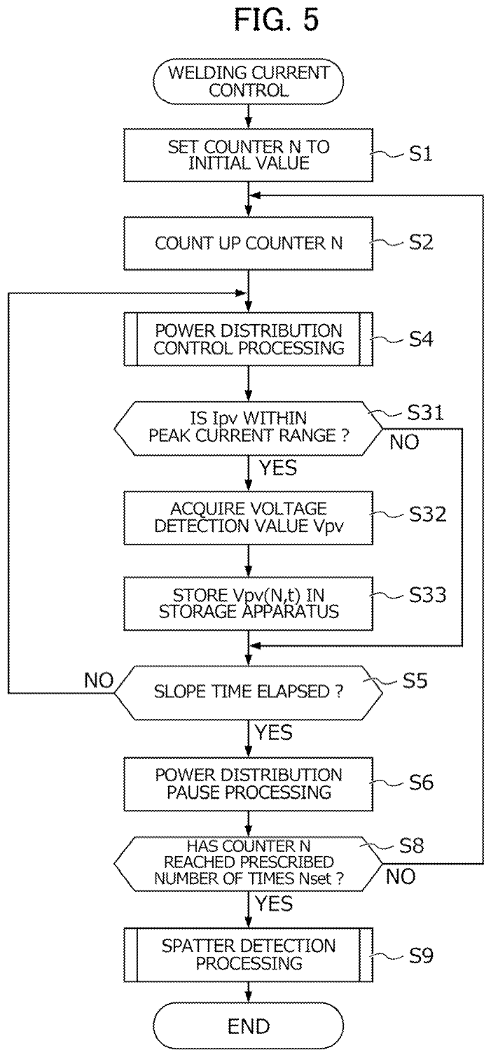

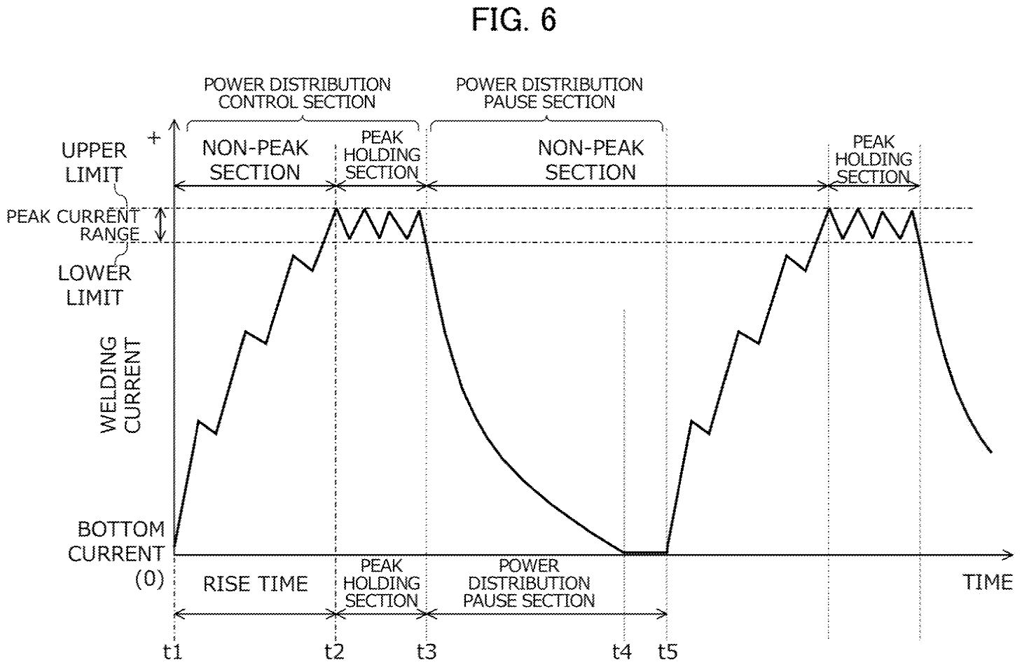

As shown in FIG. 3, the welding current Iw increases as a duty cycle increases, the duty cycle being the ratio of a pulse width PW as a period in which the AC voltage Vt is Hi or Lo to a predetermined carrier cycle T. As described later with reference to FIGS. 5 and 6, the control apparatus 33 determines the pulse width PW according to a known feedback control rule such as PI control such that the output current of the welding power circuit 3 detected by the current sensor 3d reaches a target current set by not-shown processing, and performs ON/OFF drive of the plurality of switching elements in the inverter circuit 32 by PWM control with the duty cycle set according to the pulse width PW.

Next, the steps of the spot welding method for joining the workpiece W by the welding system S as described above will be described.

First, as shown in FIG. 1, the robot control apparatus 62 drives the robot body 60 and the articulated arm 61, thereby controlling the position and posture of the spot welding apparatus 1 such that the workpiece W is arranged between the upper electrode chip 21 and the lower electrode chip 26. At this point, the robot control apparatus 62 controls the position and posture of the spot welding apparatus 1 such that the lower electrode chip 26 contacts a lower surface of the third metal plate W3 of the workpiece W.

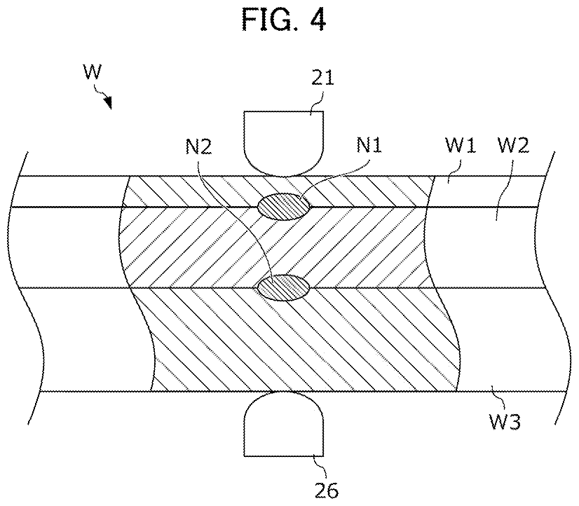

Next, as shown in FIG. 4, the upper adaptor body 23 is slid using the upper electrode chip movement mechanism 4 such that the upper electrode chip 21 approaches the lower electrode chip 26. When the upper electrode chip 21 approaches the lower electrode chip 26 and comes into contact with an upper surface of the first metal plate W1, the workpiece W is sandwiched and pressurized by the upper electrode chip 21 and the lower electrode chip 26.

Next, the control apparatus 33 of the welding power circuit 3 executes the welding current control by the steps described with reference to FIG. 5 while maintaining a state in which the workpiece W is pressurized from both sides by the electrode chips 21, 26, and applies the pulse-shaped welding current to between the upper electrode chip 21 and the lower electrode chip 26. In this manner, as shown in FIG. 4, a first nugget N1 is formed between the first metal plate W1 and the second metal plate W2, and a second nugget N2 is formed between the second metal plate W2 and the third metal plate W3. Thus, the first to third metal plates W1 to W3 are welded to each other.

FIG. 5 is a flowchart showing the specific steps of the welding current control in the control apparatus 33. FIG. 6 is a graph showing the waveform of the welding current achieved by the welding current control of FIG. 5. As shown in FIG. 6, the welding current generated by the welding current control of FIG. 5 has a pulse-shaped waveform that peak holding sections in which the welding current is maintained within a set peak current range and non-peak sections in which the welding current increases to the peak current range again after decreases to a bottom current (e.g., zero) from the peak current range are alternately achieved. In other words, under the welding current control of FIG. 5, after the welding current increases from the bottom current toward the peak current range, power distribution control to maintain the welding current within the peak current range and a power distribution pause to decrease the welding current from the peak current range toward the bottom current are alternately executed for a plurality of cycles (at least, two or more cycles), whereby a welding current having a pulse-shaped waveform as shown in FIG. 6 is generated and supplied to the workpiece W. Hereinafter, a section in which the power distribution control is performed is referred to as a power distribution control section, and a section in which the power distribution pause is performed is referred to as a power distribution pause section.

First, at S1, the control apparatus 33 sets a value of a counter N for counting the number of pulse cycles (number of pulses) of the welding current supplied to the workpiece W to an initial value of 0, and proceeds to S2.

Next, at S2, the control apparatus 33 counts up the counter N by 1 (N=N+1), and proceeds to S4.

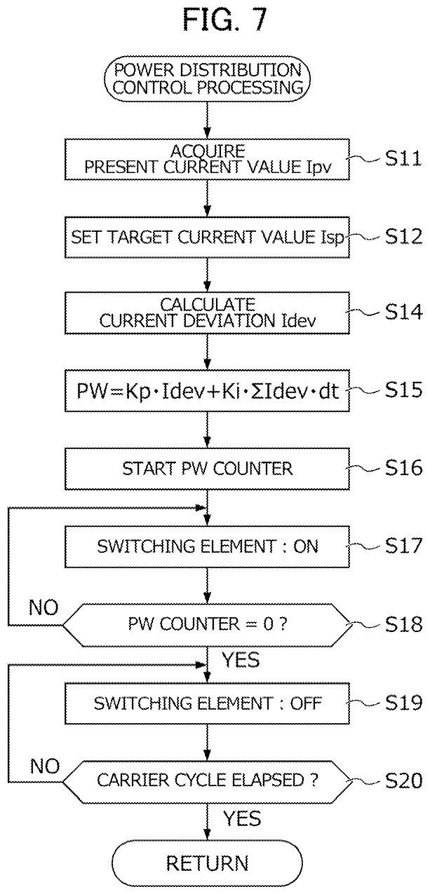

Next, at S4, the control apparatus 33 executes power distribution control processing, and proceeds to S31. As described later with reference to FIG. 7, in the power distribution control processing, the control apparatus 33 increases the welding current from the bottom current toward the peak current range, and then maintains the welding current within the peak current range for a predetermined time.

Next, at S31, the control apparatus 33 determines whether or not a present current value Ipv acquired at S11 (see FIG. 7 to be described later) in the power distribution control processing at S4 is within the peak current range, that is, whether or not the present current value is within the peak holding section. When the determination result at S31 is YES, the control apparatus 33 proceeds to S32, acquires a voltage detection value Vpv using the voltage detection signal transmitted from the voltage sensor 3e, and proceeds to S33. At S33, the control apparatus 33 stores the voltage detection value Vpv acquired at S32 together with the counter N indicating the present number of cycles and the present time point t in a storage apparatus (not shown), and proceeds to S5. In the following description, a voltage detection value at time point t in the peak holding section for an N-th cycle is written as Vpv(N, t). Further, When the determination result at S31 is NO, the control apparatus 33 does not acquire and store the voltage detection value Vpv, and proceeds to S5.

Next, at S5, the control apparatus 33 determines whether or not a predetermined slope time has elapsed. As shown in FIG. 5, this slope time is time obtained in such a manner that current rise time which is time until the welding current reaches the upper limit of the peak current range from the bottom current and peak holding time which is time for which the welding current is maintained within the peak current range are added up, and is fixed at a preset time. In other words, the slope time is fixed for all cycles of the welding current pulse. The control apparatus 33 returns to S4 to continuously execute the power distribution control processing in a case where a determination result at S5 is NO, and proceeds to S6 in a case where the determination result at S5 is YES.

Next, at S6, the control apparatus 33 executes power distribution pause processing, and then proceeds to S8. In this power distribution pause processing, the control apparatus 33 waits for execution of the power distribution control processing for a predetermined set pause time (see FIG. 6). In the present embodiment, the case has been described in which the power distribution pause is executed for a fixed set pause time, but the present invention is not limited thereto. The set pause time may be set according to the effective value of the detection value of the welding current, for example.

Next, at S8, the control apparatus 33 determines whether or not the counter N has reached a predetermined prescribed number of cycles Nset. The prescribed number of cycles Nset corresponds to the number of cycles of the welding current pulse required to join one spot of the workpiece W by the spot welding apparatus 1, and is set in advance according to the thickness and material characteristics of the workpiece W. When the determination result at S8 is NO, the control apparatus 33 returns to S2, and starts power distribution control processing for the next cycle. When the determination result at S8 is YES, the control apparatus 33 proceeds to S9. In the present embodiment, the case has been described in which the welding current is continuously supplied until the number of cycles of the welding current pulse reaches the predetermined prescribed number of cycles Nset, but the present invention is not limited thereto. For example, the welding current may be continuously supplied until a predetermined power distribution time elapses after the start of the welding current control for the first cycle.

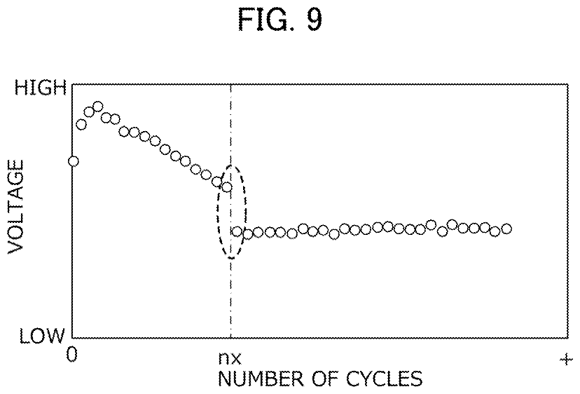

Next, at S9, the control apparatus 33 ends the processing of FIG. 5 to start joining a next spot of the workpiece W or another workpiece W after executing the spatter detection processing. As described later in detail with reference to FIG. 9, in such spatter detection processing, based on the voltage detection value detected by the voltage sensor 3e in the peak holding section for each cycle and stored in the storage apparatus, the presence or absence of the occurrence of spatter while the welding current is being supplied, the timing of the occurrence of spatter, and the quality of the product due to the occurrence of spatter are determined.

As described above, in the welding current control, the control apparatus 33 repeatedly executes the power distribution control processing (see S4) and the power distribution pause processing (see S6) across the power distribution time, thereby applying the welding current with the pulse-shaped waveform as shown in FIG. 6 to between the electrode chips 21 and 26.

FIG. 7 is a flowchart showing the specific steps of the power distribution control processing. First, at S11, the control apparatus 33 acquires, using the current detection signal transmitted from the current sensor 3d, a present current value Ipv as a present welding current value, and proceeds to S12. At S12, the control apparatus 33 sets a target current value Isp equivalent to a target welding current value, and proceeds to S14. As shown in FIG. 6, the target current value Isp is set between predetermined current rise slopes or between the upper limit and the lower limit of the peak current range.

At S14, the control apparatus 33 calculates a current deviation Idev by subtracting the present current value Ipv acquired at S11 from the target current value Isp set at S12, and proceeds to S15.

At S15, the control apparatus 33 calculates the pulse width PW according to the feedback control rule (specifically, e.g., a PI control rule) based on the current deviation Idev calculated at S14 such that the current deviation Idev reaches zero, and proceeds to S16. More specifically, the control apparatus 33 adds up the result of multiplication of the current deviation Idev by a predetermined proportional gain Kp and the result of multiplication of an integral value of the current deviation Idev by a predetermined integral gain Ki, thereby calculating the pulse width PW.

At S16, the control apparatus 33 starts a PW counter, and proceeds to S17. At S17, the control apparatus 33 turns on the switching elements provided in the inverter circuit 32, and proceeds to S18. At S18, the control apparatus 33 determines whether or not the value of the PW counter reaches zero, i.e., whether or not time equivalent to the pulse width PW has elapsed after the start of the PW counter at S16. The control apparatus 33 returns to S17 to keep the switching elements ON in a case where a determination result at S18 is NO, and proceeds to S19 in a case where the determination result at S18 is YES.

At S19, the control apparatus 33 turns off the switching elements provided in the inverter circuit 32, and proceeds to S20. At S20, the control apparatus 33 determines whether or not the set carrier cycle has elapsed after the switching elements have been turned on at S17. The control apparatus 33 returns to S19 to keep the switching elements OFF in a case where a determination result at S20 is NO, and proceeds to S5 of FIG. 5 in a case where the determination result at S20 is YES.

Next, the waveform of the welding current generated by execution of the welding current control as described above will be described in detail with reference to FIG. 6.

First, the control apparatus 33 repeatedly executes, between time points t1 to t3, the power distribution control processing shown in FIG. 7 until a lapse of the preset slope time. As described with reference to FIG. 7, in this power distribution control processing, the target current value Isp is set, and the pulse width PW is determined by the PI control such that the present current value Ipv acquired through the current sensor 3d reaches the target current value Isp. The inverter circuit 32 is driven by the PWM control with the pulse width PW. Accordingly, as shown in FIG. 6, the welding current increases from the bottom current to the peak current range after the time point t1, and reaches the upper limit of the peak current range at the time point t2. Thereafter, at the end of the power distribution control section after the time point t2, the welding current is maintained within the peak current range by the PI control in the control apparatus 33. In other words, a section between the time points t2 and t3 is a peak holding section in which the welding current is maintained within the peak current range. Further, the voltage detection value detected by the voltage sensor 3e in the peak holding section is stored in the storage apparatus for each cycle (see S31 to S33 in FIG. 5). Thereafter, at the time point t3, the control apparatus 33 ends the power distribution control processing (see S4) according to the fact that the predetermined slope time has elapsed after the start of the current control processing at the time point t1 (see S5), and starts the power distribution pause processing (see S6).

By execution of the power distribution control processing as described above, the welding current maintained within the peak current range is applied to the workpiece W. Thus, as shown in FIG. 4, growth of the nuggets N1, N2 is accelerated between the first metal plate W1 and the second metal plate W2 and between the second metal plate W2 and the third metal plate W3. Here, as shown in FIG. 4, since the thickness of the first metal plate W1 is smaller than each of the thicknesses of the second metal plate W2 and the third metal plate W3, the first metal plate W1 is easily deformed by pressurization. Thus, a contact area between the first metal plate W1 and the second metal plate W2 is larger than a contact area between the second metal plate W2 and the third metal plate W3. Thus, a contact resistance between the first metal plate W1 and the second metal plate W2 is smaller than a contact resistance between the second metal plate W2 and the third metal plate W3. Thus, Joule heat generated due to the contact resistance caused by the flow of welding current is greater at a portion between the second metal plate W2 and the third metal plate W3 than at a portion between the first metal plate W1 and the second metal plate W2. Thus, in the peak state, the growth rate of the nugget N2 generated between the second metal plate W2 and the third metal plate W3 is higher than the growth rate of the nugget N1 between the first metal plate W1 and the second metal plate W2.

Returning to FIG. 6, the control apparatus 33 executes the power distribution pause processing (see S6 in FIG. 5) between the time points t3 to t5. In the power distribution pause processing, the control apparatus 33 stops driving the inverter circuit 32 until a predetermined set pause time elapses and pauses the power distribution control. Thus, after the time point t3, the welding current quickly decreases to the bottom current, and reaches the bottom current at the time point t4. Thereafter, at the time point t5, according to the fact that the predetermined set pause time has elapsed after the start of the power distribution pause at the time point t3, the control apparatus 33 ends the power distribution pause processing and starts the power distribution control processing for the next cycle. Thus, after the time point t5, the welding current increases from the bottom current to the peak current range again.

By execution of the power distribution pause processing as described above, the driving of the inverter circuit 32 is stopped until the set pause time elapses. Thus, a state in which the welding current is limited to equal to or lower than the lower limit of the peak current range is maintained during the power distribution pause processing, and therefore, each of the nuggets N1 and N2 generated between the metal plates is cooled by heat dissipation. As described above, the thickness of the first metal plate W1 is smaller than each of the thicknesses of the second metal plate W2 and the third metal plate W3. Thus, heat dissipation between the second metal plate W2 and the third metal plate W3 is smaller than heat dissipation between the first metal plate W1 and the second metal plate W2. While the state in which the welding current is limited to equal to or lower than the peak current range is maintained, the amount of cooling of the nugget N2 by heat dissipation is greater than the amount of cooling of the nugget N1 by heat dissipation. Since the growth rate of the nugget N2 is higher than the growth rate of the nugget N1 in the peak state as described above, the state in which the welding current is limited to equal to or lower than the peak current range is maintained for the set pause time in this manner, and cooling of the nugget N2 is accelerated, whereby the spatter can be prevented from occurring between the second metal plate W2 and the third metal plate W3.

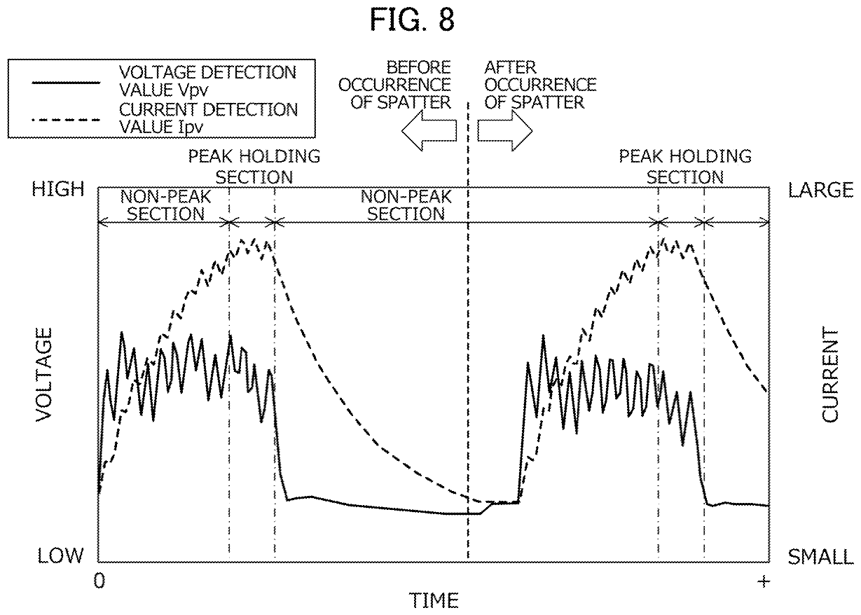

FIG. 8 is a graph showing waveforms of the current detection value Ipv and the voltage detection value Vpv for two cycles before and after the occurrence of spatter.

When the spatter occurs while the welding current is being supplied to the workpiece W, since the resistance of the workpiece W is rapidly reduced, the voltage of the workpiece W drops. For this reason, when a sudden drop in the voltage of the workpiece W can be detected, the occurrence of spatter can also be detected.

On the other hand, while the welding current is supplied to the workpiece W from the spot welding apparatus 1, a circuit formed by a combination of the workpiece W and the spot welding apparatus 1 including the chips 21 and 26 and the welding power circuit 3 can be regarded as an RL series circuit in which a resistance element corresponding to the workpiece W and an inductance element corresponding to the welding power circuit 3 and the gun arm 25 are connected in series. For this reason, when the welding current, which changes with time in a pulse shape, is supplied to the workpiece by alternately repeating the power distribution control processing and the power distribution pause processing by the welding power circuit 3 over a plurality of cycles, the voltage sensor 3e provided in the welding power circuit 3 is affected by the inductance element, and thus cannot detect only the voltage of the workpiece W.

Therefore, in the non-peak section where the welding current fluctuates greatly as shown in FIG. 8, since the voltage detection value Vpv detected by the voltage sensor 3e includes not only the voltage of the workpiece W, but also the voltage drop in the inductance element that is proportional to the rate of change of the welding current, a sudden drop in the voltage detection value Vpv due to the occurrence of spatter cannot be detected. On the other hand, in the peak holding section, since the change in the welding current over time is small and the influence of the inductance element can be ignored, the voltage detection value Vpv significantly decreases from before to after the occurrence of spatter compared to the non-peak section, as shown in FIG. 8.

Therefore, in the spatter detection processing, the presence or absence of the occurrence of spatter is determined based on the voltage detection value Vpv detected by the voltage sensor 3e in the peak holding section acquired for each cycle by the processing at S31 to S33 in FIG. 5.

FIG. 9 is a graph obtained by plotting average values of the voltage detection values Vpv for each cycle in the peak holding section. FIG. 9 shows a case where the spatter occurs for an nx-th cycle. As shown in FIG. 9, the average value of the voltage detection values Vpv for each cycle in the peak holding section significantly decreases from before to after the occurrence of spatter.

As described with reference to FIG. 8, the voltage detection value Vpv in the peak holding section changes significantly before and after the spatter occurs. However, since the welding current fluctuates within the peak current range even in the peak holding section, the voltage detection value Vpv also fluctuates. Therefore, the occurrence of spatter cannot be accurately detected from the voltage detection value Vpv, which is an instantaneous value. On the other hand, as shown in FIG. 9, the change caused by the occurrence of spatter can be made more conspicuous using the average value of the voltage detection values Vpv for each cycle in the peak holding section.

Therefore, in the spatter detection processing, the average value of the voltage detection values Vpv for each cycle in the peak holding section is calculated based on the voltage detection values Vpv detected by the voltage sensor 3e in the peak holding section acquired for each cycle by the processing at S31 to S33 in FIG. 5, and further, the presence or absence of the occurrence of spatter is determined based on the average value for each cycle.

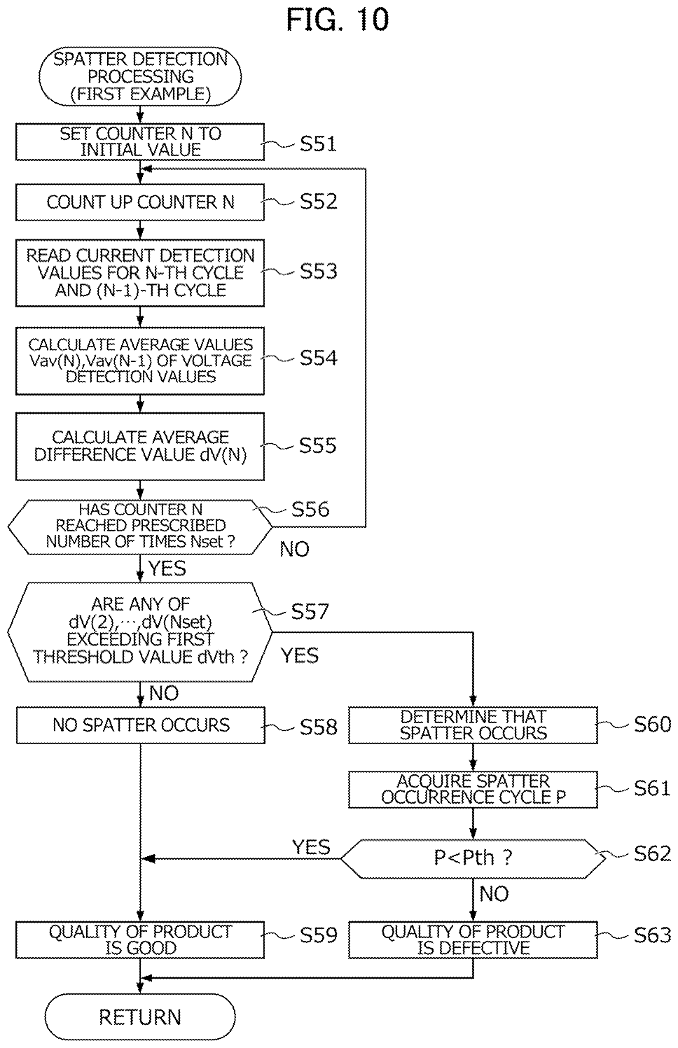

FIG. 10 is a flowchart showing the specific steps in the spatter detection processing of a first example.

First, at S51, the control apparatus 33 sets the counter N for counting the number of cycles to an initial value of 1, and proceeds to S52.

Next, at S52, the control apparatus 33 counts up the counter N by 1 (N=N+1), and proceeds to S53.

Next, at S53, the control apparatus 33 sets the N-th cycle as a target cycle, reads voltage detection values (Vpv(N, t1), Vpv(N, t2), . . . ) at respective time points in a peak holding section for the target cycle and voltage detection values (Vpv(N−1, t1), vpv(N−1, t2), . . . ) at respective time points in a peak holding section for an M-th cycle (M being an integer smaller than N) before the target cycle, more specifically, for an (N−1)-th cycle immediately before the target cycle from the storage apparatus (not shown), and proceeds to S54.

Next, at S54, the control apparatus 33 calculates an average value Vav(N) of the voltage detection values in the peak holding section for the N-th cycle and an average value Vav(N−1) of the voltage detection values in the peak holding section for the (N−1)-th cycle, based on the data read at S53, and proceeds to S55.

Next, at S55, the control apparatus 33 calculates an average difference value dV(N) by subtracting the average value Vav(N) of the voltage detection values in the peak holding section for the N-th cycle from the average value Vav(N−1) of the voltage detection values in the peak holding section for the (N−1)-th cycle, stores the value in the storage apparatus (not shown), and proceeds to S56.

Next, at S56, the control apparatus 33 determines whether or not the counter N has reached the prescribed number of cycles Nset. When the determination result in at S56 is NO, the control apparatus 33 returns to S52, and when the determination result at S56 is YES, the control apparatus 33 proceeds to S57.

Next, at S57, the control apparatus 33 determines in order to determine the presence or absence of the occurrence of spatter whether or not there is any one of the average difference values dV(2), . . . , dV(Nset) for Nset-1 cycles that exceeds a predetermined first threshold value dVth.

When the determination result at S57 is NO, that is, when all of the average difference values dV(2), . . . , dV(Nset) for Nset-1 cycles are less than the first threshold value dVth, the control apparatus 33 proceeds to S58, determines that no spatter occurs, and proceeds to S59. At S59, the control apparatus 33 determines that the quality of the product manufactured by joining the workpiece W is good, and ends the processing of FIG. 8.

Further, when the determination result at S57 is YES, that is, when at least one of the average difference values dV(2), . . . , dV(Nset) for Nset-1 cycles exceeds the first threshold value dVth, the control apparatus 33 proceeds to S60, determines that the spatter occurs, and proceeds to S61.

At S61, the control apparatus 33 calculates a spatter occurrence cycle P equivalent to a timing at which the spatter occurs, and proceeds to S62. More specifically, the control apparatus 33 acquires a cycle at which any of the average difference values dV(2), . . . , dV(Nset) for Nset-1 cycles exceeds the first threshold value dVth, and sets such a cycle as the spatter occurrence cycle P. Here, when there are a plurality of cycles at which any of the average difference values dV(2), . . . , dV(Nset) for Nset-1 cycles exceeds the first threshold value dVth, it is preferable to set a final cycle, at which the average difference value exceeds the first threshold value dVth at last, as the spatter occurrence cycle P.

At S62, the control apparatus 33 determines in order to determine the quality of the product based on the timing of the occurrence of spatter whether or not the spatter occurrence cycle P is less than a cycle threshold value Pth set from 2 to Nset.

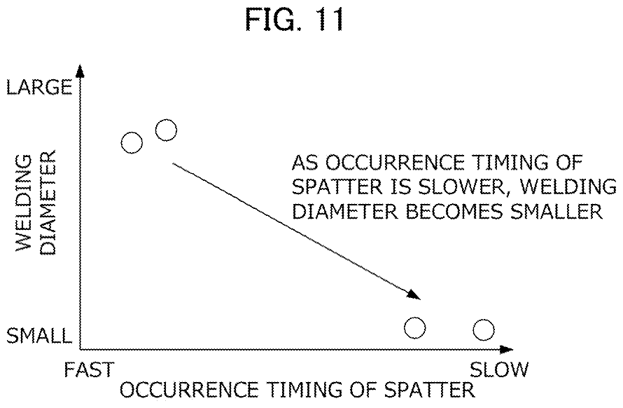

FIG. 11 is a graph showing a correlation between a welding diameter (i.e., welding strength) formed when the welding current is continuously supplied over the prescribed cycle Nset and the timing of the occurrence of spatter. As shown in FIG. 11, the slower the timing of the occurrence of spatter, the smaller the welding diameter formed finally by welding, and accordingly the lower the welding strength. It is considered that this is because when the timing of the occurrence of spatter is at a former period of the welding, the welding diameter can be expected to grow with subsequent power distribution, whereas when the timing of the occurrence of spatter is at a latter period of the welding, the welding diameter does not grow sufficiently due to subsequent power distribution.

Returning to FIG. 10, when the determination result at S62 is YES, that is, when the spatter occurrence cycle P is less than the cycle threshold value Pth, the control apparatus 33 proceeds to S59, determines that the quality of the product is good, and ends the processing of FIG. 10. Further, when the determination result at S62 is NO, that is, when the spatter occurrence cycle P is equal to or greater than the cycle threshold value Pth, the control apparatus 33 proceeds to S63, determines that the quality of the product is defective, and ends the processing of FIG. 10.

In addition, it is preferable to check the quality again by visual inspection when it is determined that the quality of the product is defective by the above-described spatter detection processing.

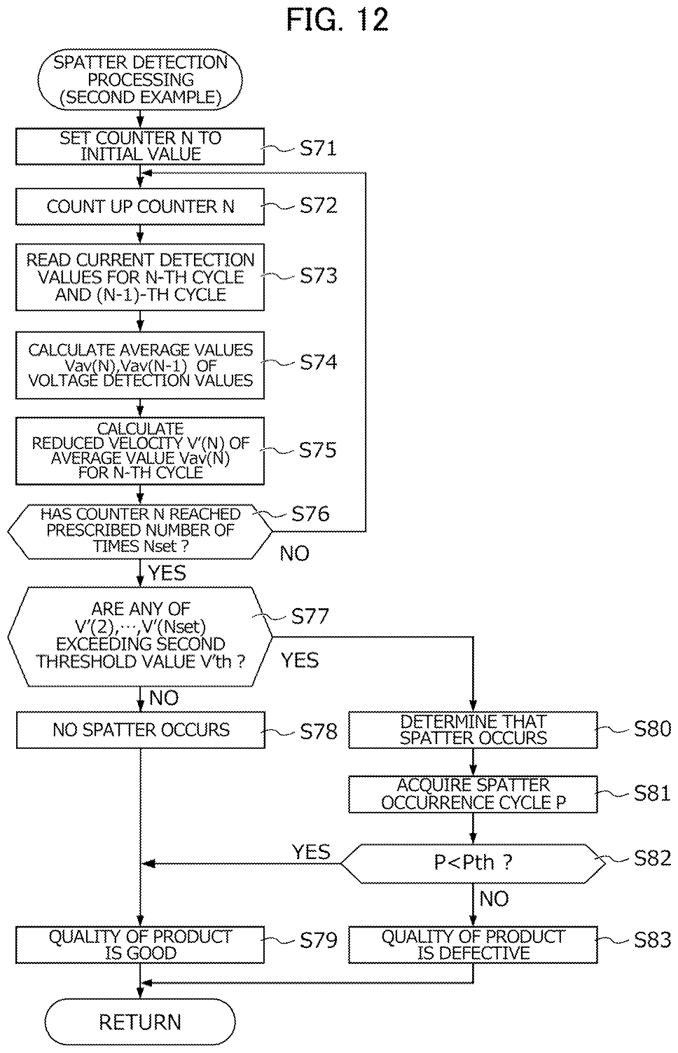

FIG. 12 is a flowchart showing the specific steps in the spatter detection processing of a second example. In the processing shown in FIG. 12, steps S71 to S74, S76, and S78 to S83 are the same as steps S51 to S54, S56, and S58 to S63 in the processing shown in FIG. 10, respectively, and thus will not be described.

At S75, the control apparatus 33 calculates a reduced velocity V′(N) with respect to a change in the number of cycles of the average value Vav(N), based on the average values Vav(N) and Vav(N−1) of the voltage detection values in the peak holding section for the N-th cycle and the (N−1)-th cycle, and stores the reduced velocity in the storage apparatus (not shown), and proceeds to S76. More specifically, the control apparatus 33 divides the value obtained by subtracting the average value Vav(N) for the N-th cycle from the average value Vav(N−1) for the (N−1)-th cycle by a predetermined time to calculate the reduced velocity V′(N).

At S77, the control apparatus 33 determines in order to determine the presence or absence of the occurrence of spatter whether or not there is any one of the reduced velocities V′(2), . . . , V′(Nset) for Nset-1 cycles that exceeds a predetermined second threshold value V'th.

When the determination result at S77 is NO, that is, when all of the reduced velocities V′(2), . . . , V′(Nset) for Nset-1 cycles are less than the second threshold value V'th, the control apparatus 33 proceeds to S78. In addition, when the determination result at S77 is YES, that is, when at least one of the reduced velocities V′(2), . . . , V′(Nset) for Nset-1 cycles exceeds the second threshold value V'th, the control apparatus 33 proceeds to S80.

According to the spatter detection method related to the present embodiment, the following effects are achieved.

(1) The circuit formed by a combination of the workpiece W, the pair of electrode chips 21 and 26 that sandwich the workpiece W, and the welding power circuit 3 connected to the pair of electrode chips 21 and 26 can be regarded as an RL series circuit in which the resistance element corresponding to the workpiece W and the inductance element corresponding to the welding power circuit 3 are connected in series. For this reason, when the welding current, which changes with time in a pulse shape, is supplied to the workpiece W by alternately repeating the power distribution control and the power distribution pause by the welding power circuit 3 over a plurality of cycles, the voltage sensor 3e provided in the welding power circuit 3 is affected by the inductance element, and thus cannot detect the voltage between the pair of electrode chips 21 and 26, that is, the voltage of the workpiece W. Therefore, in the present embodiment, the voltage detection value Vpv detected by the voltage sensor 3e in the peak holding section in which the welding current is maintained within the set peak current range is acquired for each cycle, and the presence or absence of the occurrence of spatter is determined, based on the difference value between the voltage detection values (Vpv(N, t1), Vpv(N, t2), . . . ) in the peak holding section for the N-th cycle and the voltage detection values (Vpv(M, t1), Vpv(M, t2), . . . ) in the peak holding section for the M-th cycle before the N-th cycle. In such a peak holding section, since the welding current changes little over time, the voltage sensor 3e provided in the welding power circuit 3 can detect the voltage of the workpiece W while ignoring the influence of the inductance element. Therefore, according to the present embodiment, the voltage sensor 3e provided in the welding power circuit 3 can detect the voltage drop in the workpiece W due to the occurrence of spatter while the welding current is being supplied, and can detect the occurrence of spatter as a result.

(2) When the pulse-shaped welding current as described above continues to be supplied over a plurality of cycles, the voltage of the workpiece W will gradually change even when the spatter does not occur. Therefore, in the present embodiment, the voltage detection value in the peak holding section for the M-th cycle (i.e., M=N−1) immediately before the N-th cycle is used as a comparison target for the voltage detection value in the peak holding section for the N-th cycle, whereby it is possible to determine the presence or absence of the occurrence of spatter and the cycle of the occurrence of spatter with high accuracy.

(3) In the peak holding section, the welding current is maintained within the peak current range, but fluctuates slightly. Therefore, in the present embodiment, the average value of the voltage detection values in the peak holding section is calculated for each cycle, and it is determined that the spatter occurs when the difference value dV(N) obtained by subtracting the average value Vav(N) for the N-th cycle from the average value Vav(N−1) for the (N−1)-th cycle is larger than the predetermined first threshold value dVth. By using the average value of the voltage detection values in the peak holding section in this manner, the voltage of the workpiece W can be detected while ignoring the influence caused by the slight change in the current as described above, whereby it is possible to determine the presence or absence of the occurrence of spatter and the cycle of the occurrence of spatter with high accuracy.

(4) In the present embodiment, the voltage detection value detected by the voltage sensor 3e in the peak holding section in which the welding current is maintained within the set peak current range is acquired for each cycle, and the presence or absence of the occurrence of spatter is determined, based on the reduced velocity with respect to the change in the number of cycles of the voltage detection value. In such a peak holding section, since the welding current changes little over time, the voltage sensor 3e provided in the welding power circuit 3 can detect the voltage of the workpiece W while ignoring the influence of the inductance element. Therefore, according to the present embodiment, the voltage sensor 3e provided in the welding power circuit 3 can detect the voltage drop in the workpiece W due to the occurrence of spatter while the welding current is being supplied, and can detect the occurrence of spatter as a result.

(5) In the present embodiment, the average value Vav(N) of the voltage detection values in the peak holding section is calculated for each cycle, and it is determined that the spatter occurs when the reduced velocity V′(N) with respect to the change in the number of cycles of the average value Vav(N) is larger than the predetermined second threshold value V'th. By using the average value Vav(N) of the voltage detection values in the peak holding section in this manner, the voltage of the workpiece W can be detected while ignoring the influence caused by the slight change in the current in the peak holding section, whereby it is possible to determine the presence or absence of the occurrence of spatter and the cycle of the occurrence of spatter with high accuracy.

One embodiment of the present invention has been described above, but the present invention is not limited to above. Detailed configurations may be changed as necessary within the scope of the gist of the present invention.

In the present embodiment, the case has been described in which the spatter detection processing is executed after the welding current is supplied over the prescribed cycle Nset to detect the occurrence of spatter, but the execution timing for the spatter detection processing is not limited thereto. In the spatter detection processing according to the present invention as described above, the occurrence of spatter is detected, based on the average value of the voltage detection values Vpv detected by the voltage sensor 3e in the peak holding section for the target cycle, and thus the spatter detection processing may be executed while the welding current is supplied.

What is claimed is:

1. A spatter detection method for detecting an occurrence of spatter at the time of joining a workpiece, which is a multilayer body of a plurality of plates, using a welding apparatus including a pair of electrodes, a welding power circuit connected to the pair of electrodes, and a voltage sensor configured to detect a voltage in the welding power circuit, wherein
a spot welding method using the welding apparatus includes supplying a pulse-shaped welding current to the workpiece, the pulse-shaped welding current being generated when the welding power circuit alternately repeats power distribution control and a power distribution pause over a plurality of cycles while the workpiece is sandwiched and pressurized by the pair of electrodes, and maintaining, under the power distribution control, the welding current within a set peak current range in a peak holding section,
the spatter detection method comprising:
a step of acquiring voltage detection values detected by the voltage sensor in the peak holding section for each of the cycles; and
a step of determining whether or not the spatter occurs, based on a difference value between the voltage detection values in the peak holding section for an N-th cycle (N being an integer equal to or greater than 2) and the voltage detection values in the peak holding section for an M-th cycle (M being an integer smaller than N).

2. The spatter detection method according to claim 1, wherein the M-th cycle is a cycle immediately before the N-th cycle.

3. The spatter detection method according to claim 2, further comprising a step of calculating an average value of the voltage detection values in the peak holding section for each of the cycles, wherein
it is determined that the spatter occurs when an average difference value is larger than a predetermined first threshold value, the average difference value being obtained by subtracting the average value for the N-th cycle from the average value for the M-th cycle.

4. A spatter detection method for detecting an occurrence of spatter at the time of joining a workpiece, which is a multilayer body of a plurality of plates, using a welding apparatus including a pair of electrodes, a welding power circuit connected to the pair of electrodes, and a voltage sensor configured to detect a voltage in the welding power circuit, wherein
a spot welding method using the welding apparatus includes supplying a pulse-shaped welding current to the workpiece, the pulse-shaped welding current being generated when the welding power circuit alternately repeats power distribution control and a power distribution pause over a plurality of cycles while the workpiece is sandwiched and pressurized by the pair of electrodes, and maintaining, under the power distribution control, the welding current within a set peak current range in a peak holding section,
the spatter detection method comprising:
a step of acquiring voltage detection values detected by the voltage sensor in the peak holding section for each of the cycles; and
a step of determining whether or not the spatter occurs, based on a reduced velocity with respect to a change in a number of cycles of the voltage detection values.

5. The spatter detection method according to claim 4, further comprising a step of calculating an average value of the voltage detection values in the peak holding section for each of the cycles, wherein
it is determined that the spatter occurs when a reduced velocity with respect to a change in the number of cycles of the average value is larger than a predetermined second threshold value.
